(19) United States
(12) Patent Application Publication
(10) Pub. No.: US 2006/0118936 A1
(43) Pub. Date: Jun. 8, 2006

(54) Circuit module component mounting system and method

(75) Inventors: Russell Rapport, Austin, TX (US); David Roper, Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group L.P.

(21) Appl. No.: 11/003,168

(22) Filed: Dec. 3, 2004

(51) Int. Cl. H01L 23/02

(52) U.S. Cl. 257/686

(57) ABSTRACT

One or more capacitors are mounted within the lateral extent of a module having one or more integrated circuits. Other components may be similarly mounted. In one embodiment, multiple ICs are stacked and interconnected with flexible circuits to form a high-density module. Surface-mount capacitors may be mounted to the flexible circuits. In other embodiments, capacitors are placed at least partially within cutout spaces formed in the flexible circuits. Preferred embodiments have flex circuits with two conducive layers. Module contacts may be used to connect the module to its operating environment.

### FIELD

The present invention relates to interconnects among electronic circuits, and especially to connection topologies for circuit modules.

### BACKGROUND

Many modern integrated circuits operate at high frequencies have electrical current requirements that often experience sudden spikes, known as transients. Such transients cause noise on the power supply bus of the associated circuit. For example, in many modern digital integrated circuits (ICs) such as memory ICs, signals often transition on many terminals simultaneously. Such transition may cause large transients on the IC's power supply bus as the current demanded from the power supply bus changes rapidly.

One typical method of mitigating noise caused by such transients is the use of bypass capacitors. A power supply typically has one or more bypass capacitors to shunt the noise to ground. At high frequencies, however, the characteristic inductance of power bus transmission lines requires that a bypass capacitor be very close to each integrated circuit that receives the power. Modern circuits with demanding power supply noise margin specifications also typically require close proximity between capacitor and device. A circuit board such as, for example, a dual inline memory module board (DIMM), will typically have one or more bypass capacitors placed as close as possible to each memory IC on the DIMM. Such proximity minimizes series inductance and resistance between the bypass capacitor and the IC.

Many modern DIMM boards employ memory ICs arranged in high density stacked modules that conserve board space but tend to inhibit optimum placement of bypass capacitors. A variety of techniques are used to interconnect packaged ICs into high density stacked modules. In some techniques, flexible conductors are used to selectively interconnect packaged integrated circuits. Staktek Group, L.P. has developed numerous systems for aggregating packaged ICs in both leaded and CSP (chipscale) packages into space saving topologies. Many circuit board designs with high density stacked circuit modules place bypass capacitors on the board next to the module. Such placement is not optimum. A more optimum placement disposes a bypass capacitor as close as possible to each IC in the stacked module.

What is needed, therefore, are methods and structures for placing bypass capacitors or other circuit components close to individual ICs in high density stacked modules.

### SUMMARY

One or more capacitors or other components are mounted within the lateral extent of a module having one or more integrated circuits. In one embodiment, multiple ICs are stacked and interconnected with flexible circuits to form a high-density module. Surface-mount capacitors are mounted to the flexible circuits. In other embodiments, capacitors are placed at least partially within cutout spaces formed in the flexible circuits. Preferred embodiments have flex circuits with two conducive layers. Module contacts may be used to connect the module to its operating environment.

### BRIEF DESCRIPTION OF THE DRAWINGS

FIG. 1 shows a two-high module devised in accordance with a preferred embodiment of the invention.

FIG. 2 depicts an enlarged view of the area marked A in FIG. 1.

FIG. 3 depicts a cross-sectional view of another embodiment of the present invention.

FIG. 4 depicts a cross-section view of yet another embodiment of the present invention.

FIG. 5 depicts a bottom view of the embodiment of FIG. 4.

FIG. 6 is a cross-sectional view of a portion of a preferred embodiment depicting a preferred construction for flex circuitry.

FIG. 7 depicts a portion of a flex circuit according to one embodiment of the present invention.

FIG. 8 depicts an embodiment of a mounting pad according to another embodiment of the present invention.

FIG. 9 depicts a module according to another embodiment of the present invention.

FIG. 10 depicts a perspective view of one module according to another embodiment of the present invention.

FIG. 11 depicts a form standard according to one embodiment of the present invention.

### DETAILED DESCRIPTION OF PREFERRED EMBODIMENTS

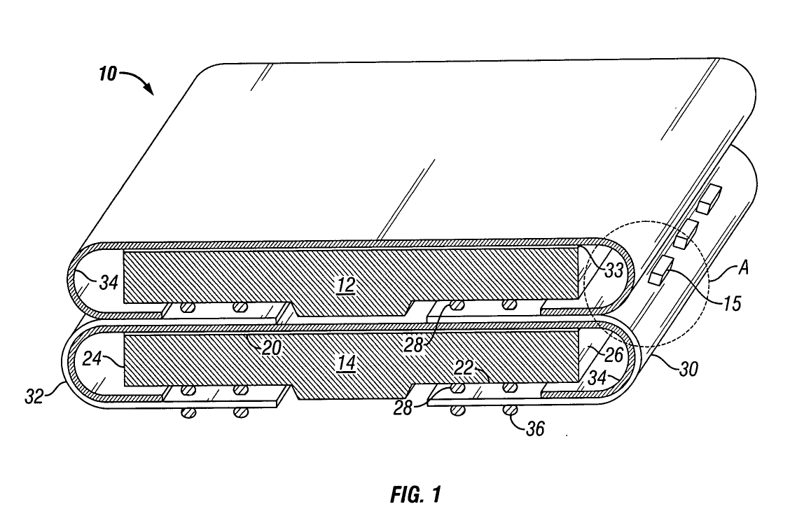

FIG. 1 shows a two-high module 10 devised in accordance with a preferred embodiment of the invention. Module 10 is comprised of two CSPs: CSP 12 and CSP 14. Capacitors 15 are mounted to module 10 in a manner described below. Flex circuitry (“flex”, “flex circuits”) is shown connecting constituent CSPs 12 and 14. A single flex circuit may be employed in place of the two depicted flex circuits 30 and 32. The entirety of the flex circuitry may be flexible or, as those of skill in the art will recognize, a PCB structure made flexible in certain areas to allow conformability around CSPs and rigid in other areas for planarity along CSP surfaces may be employed as an alternative flex circuit in the present invention. For example, structures known as rigid-flex may be employed.

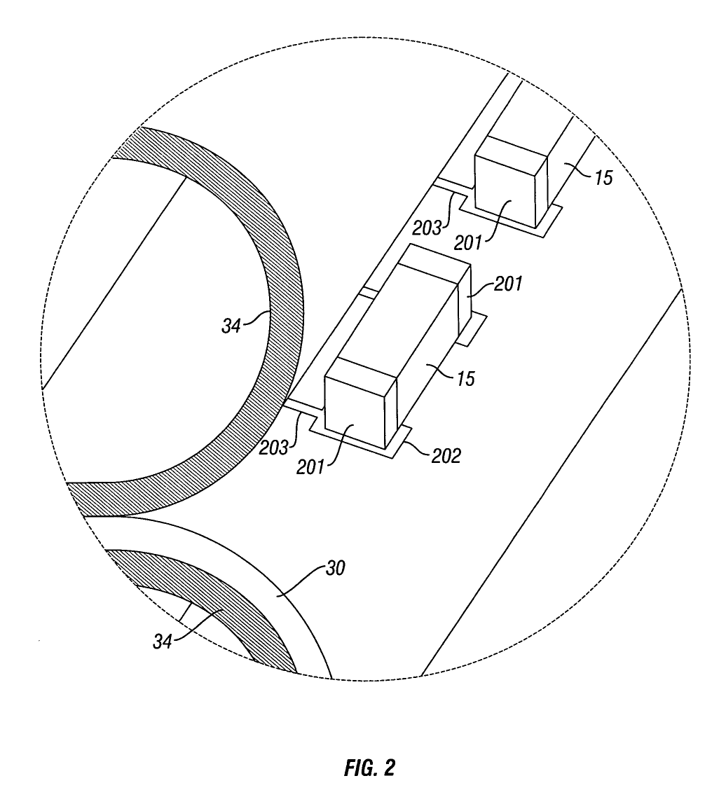

In this embodiment, capacitors 15 are mounted along the outside of flex circuit 30. The depicted capacitors 15 are surface mount capacitors (“chip capacitors”), which are mounted to conductive mounting pads presented toward the outer side of flex 30. The circle marked ‘A’ selects a portion that is depicted in the enlarged view of FIG. 2.

Continuing with reference to FIG. 1, each of the CSPs has an upper surface 20 and a lower surface 22 and opposite lateral edges 24 and 26 and typically include at least one integrated circuit surrounded by a plastic body. The body need not be plastic, but a large majority of packages in CSP technologies are plastic. Those of skill will realize that the present invention may be devised to create modules with different size CSPs and that the constituent CSPs may be of different types within the same module 10. For example, one of the constituent CSPs may be a typical CSP having lateral edges 24 and 26 that have an appreciable height to present a “side” while other constituent CSPs of the same module 10 may be devised in packages that have lateral edges that are more in the character of an edge rather than a side having appreciable height.

The term CSP should be broadly considered in the context of this application. Collectively, these will be known herein as chip scale packaged integrated circuits (CSPs) and preferred embodiments will be described in terms of CSPs, but the particular configurations used in the explanatory figures are not, however, to be construed as limiting. For example, the elevation views are depicted with CSPs of a particular profile known to those in the art, but it should be understood that the figures are exemplary only. The invention may be employed to advantage in the wide range of CSP configurations available in the art where an array of connective elements is available from at least one major surface. The invention is advantageously employed with CSPs that contain memory circuits, but may be employed to advantage with logic and computing circuits where added capacity without commensurate PWB or other board surface area consumption is desired.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 22 of a plastic casing in any of several patterns and pitches. An external portion of the connective contacts is often finished with a ball of solder. Shown in FIG. 1 are contacts 28 along lower surfaces 22 of the illustrated constituent CSPs 12 and 14. Contacts 28 provide connection to the integrated circuit or circuits within the respective packages.

A first form standard 34 is shown disposed adjacent to upper surface 20 of CSP 14. A second form standard is also shown associated with CSP 12. Form standard 34 may be fixed to upper surface 20 of the respective CSP with an adhesive 33 which preferably is thermally conductive. Form standard 34 may also, in alternative embodiments, merely lay on upper surface 20 or be separated from upper surface 20 by an air gap or medium such as a thermal slug or non-thermal layer. A form standard may be employed on each CSP in module 10 for heat extraction enhancement as shown in the depiction of FIG. 1, which is a preferred mode for the present invention where heat extraction is a high priority. In other embodiments, form standard 34 may be inverted relative to the corresponding CSP so that, for example, it would be opened over the upper surface 20 of CSP 14.

Form standard 34 is, in a preferred embodiment, devised from copper to create, as shown in the depicted preferred embodiment of FIG. 1, a mandrel that mitigates thermal accumulation while providing a standard sized form about which flex circuitry is disposed. Form standard 34 may also be devised from nickel-plated copper in preferred embodiments. Form standard 34 may take other shapes and forms such as, for example, an angular “cap” that rests upon the respective CSP body. It also need not be thermally enhancing although such attributes are preferable.

The form standard 34 allows the invention to be employed with CSPs of varying sizes, while articulating a single set of connective structures useable with the varying sizes of CSPs. Thus, a single set of connective structures such as flex circuits 30 and 32 (or a single flexible circuit in the mode where a single flex is used in place of the flex circuit pair 30 and 32) may be devised and used with the form standard 34 method and/or systems disclosed herein to create stacked modules with CSPs having different sized packages. This will allow the same flex circuitry set design to be employed to create iterations of a stacked module 10 from constituent CSPs having a first arbitrary dimension X across attribute Y (where Y may be, for example, package width), as well as modules 10 from constituent CSPs having a second arbitrary dimension X prime across that same attribute Y. Thus, CSPs of different sizes may be stacked into modules 10 with the same set of connective structures (i.e., flex circuitry). Further, as those of skill will recognize, mixed sizes of CSPs may be implemented into the same module 10, such as would be useful to implement embodiments of a system-on-a-stack such as those disclosed in co-pending application PCT/US03/29000, filed Sep. 15, 2003, which is owned by the assignee of the present application.

FIG. 2 depicts an enlarged view of the area marked A in FIG. 1. Portions of form standard 34 and flex 30 are shown cutaway to clarify the depiction. In this embodiment, capacitors 15 are mounted to mounting pads 202 disposed toward the outer surface of flex circuit 30. Mounting pads 202 may be expressed by a conductive layer at the outer surface of flex circuit 30, or may be expressed by a conductive layer below the outer surface but exposed. Capacitors 15 are preferably surface mount or chip capacitors having terminals 201 on both ends of a ceramic body. Other types of capacitors may be used. For example, chip capacitors having flexible epoxy polymer termination material may be employed to mitigate the mechanical stress failures that sometimes occur with ceramic chip capacitors.

In this embodiment, traces 203 electrically connect surface mount pads 202 to CSPs 12 and 14. Preferably, a trace 203 connects one terminal 201 of each capacitor 15 to ground. Vias may also connect terminals 201 to a ground plane or conductive traces at another conductive layer of flex circuit 30, as will be further described with regard to later-referenced Figures. In a preferred embodiment, capacitors 15 are configured as bypass, or decoupling, capacitors. Such capacitors are typically used to decouple noise on the power supply input. In such cases, the capacitor should preferably be as close as possible to the associated input contact. More than one chip capacitor 15 may be used in parallel to supplant a single capacitor as needed in a circuit design. Such a parallel combination may reduce the equivalent series resistance (ESR) and equivalent series inductance (ESL) of the bypass capacitor. Other surface mount circuit elements, such as, for example, bias or termination resistors may also be similarly mounted.

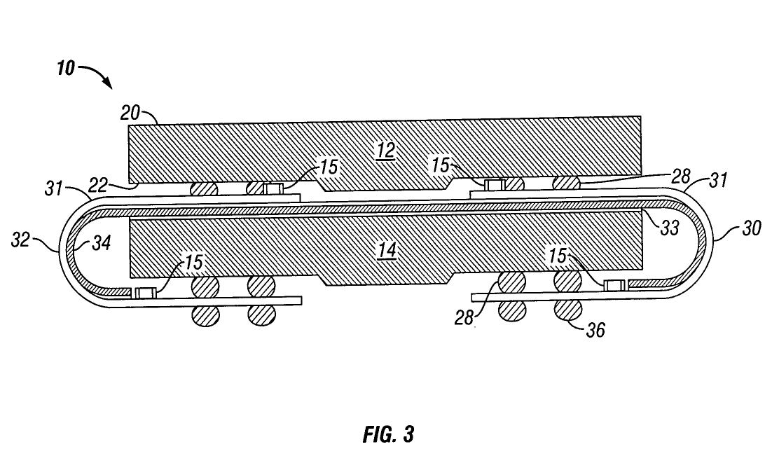

FIG. 3 depicts a cross-sectional view of another embodiment of the present invention. In this embodiment, capacitors 15 are mounted to pads 202 along the top side of flex circuits 30 and 32. Capacitors 15 are mounted in areas that are not between contacts 28 of the same array. Capacitors 15 are mounted outside of the array(s) of contacts 28 of top CSP 12, toward the sides or ends of flat portion 31 of each flex. Capacitors 15 may be mounted along the inside or outside of flex circuits 30 and 32. Further, in embodiments having no form standard 34, capacitors 15 many be mounted along the inside the depicted curve in each flex circuit. Other embodiments may have capacitors 15 mounted between multiple arrays of contacts if there is adequate inter-array spacing. Further, as with other embodiments, depicted capacitors 15 may instead be other discrete components or small packaged ICs.

Capacitors 15 are preferably placed close to respective power and ground contacts 28 of CSP 12. Preferably, the height of capacitors 15 is less than the height of a contact 28 after solder re-flow. Such height, for some BGA contacts, is around 12 mils or less. Other embodiments may feature taller capacitors mounted on portions of flex 31 that extend beyond the lateral extent of CSP 12. Such flex portions may be supported by extending portions of form standard 34. Still other embodiments may have cut-out portions or similar features in the body of CSP 12 for allowing clearance of a capacitor 15.

In a preferred method of assembling this embodiment, capacitors 15 are mounted to the depicted flex circuits before CSP 12 is mounted. In other embodiments depicted herein, capacitors 15 may be mounted before or after the CSP to which they are proximal.

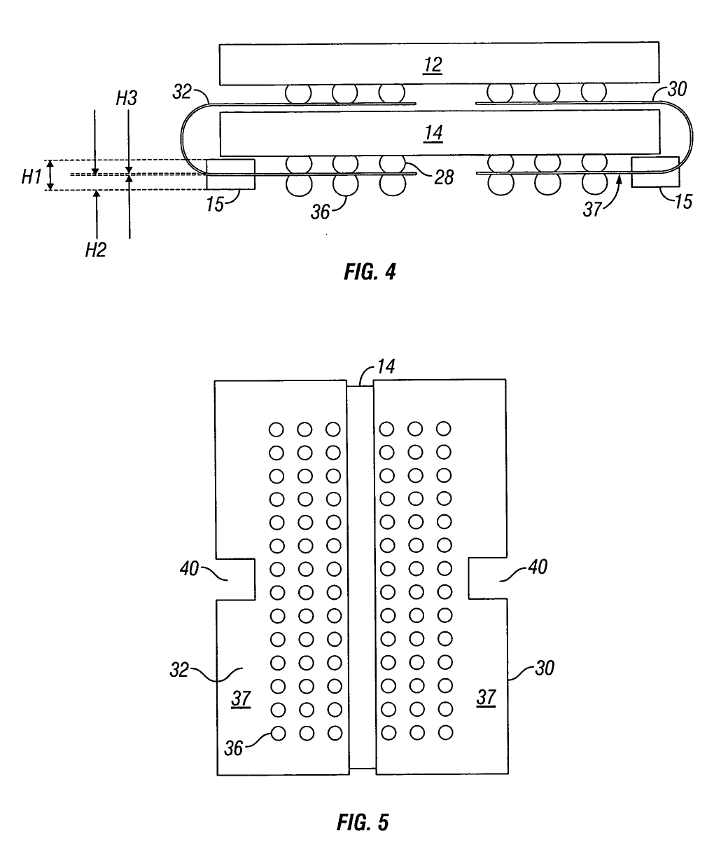

FIG. 4 depicts a cross-section view of yet another embodiment of the present invention. In this embodiment, capacitors 15 are mounted on the circuit board or other operating environment to which module 10 is also mounted. Capacitors 15 are mounted inside the “footprint” or lateral extent of circuit module 10. Flex circuits 30 and 32 are provided with cutout portions (FIG. 5) to allow mounting of capacitors having a height H1 taller than the height or diameter H2 of module contacts 36 after solder re-flow. Flex circuits 30 and 32 have lower flat portion 37 having a height H3. In this embodiment, capacitors 15 may have any height less than the total height comprising H3 plus the height of module contacts 36 after re-flow, and the height of CSP contact 28 after re-flow. In this embodiment the heights of contacts 36 and 28 are equal, producing a maximum height H1 of capacitor 15 equal to two times H2, plus H3.

FIG. 5 depicts a bottom view of the embodiment of FIG. 4. Capacitors 15 are not shown in FIG. 5 to simplify the drawing. Lower flat portions 37 of flex circuits 30 and 32 each have an array of module contacts 36. Flex circuits 30 and 32 each have a cutout portion 40 to allow for clearance of capacitor 15 (FIG. 4). Cutout portion 40 may be constructed during assembly of the flex circuit, or the cutout may be removed after construction.

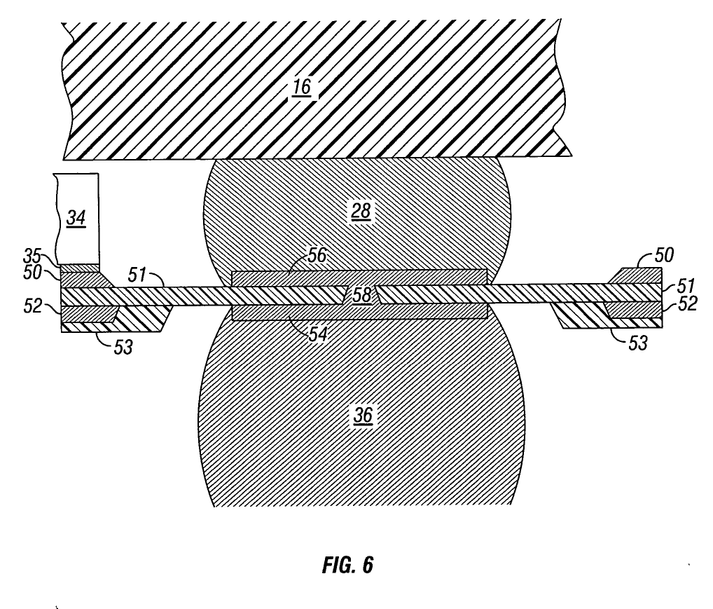

FIG. 6 is a cross-sectional view of a portion of a preferred embodiment depicting a preferred construction for flex circuitry which, in the depicted embodiment is, in particular, flexible circuit 32 which includes two conductive layers 50 and 52 separated by intermediate layer 51. Preferably, the conductive layers are metal such as alloy 110. Intermediate layer 51 is preferably a polyimide substrate, but may be other flexible circuit substrate material.

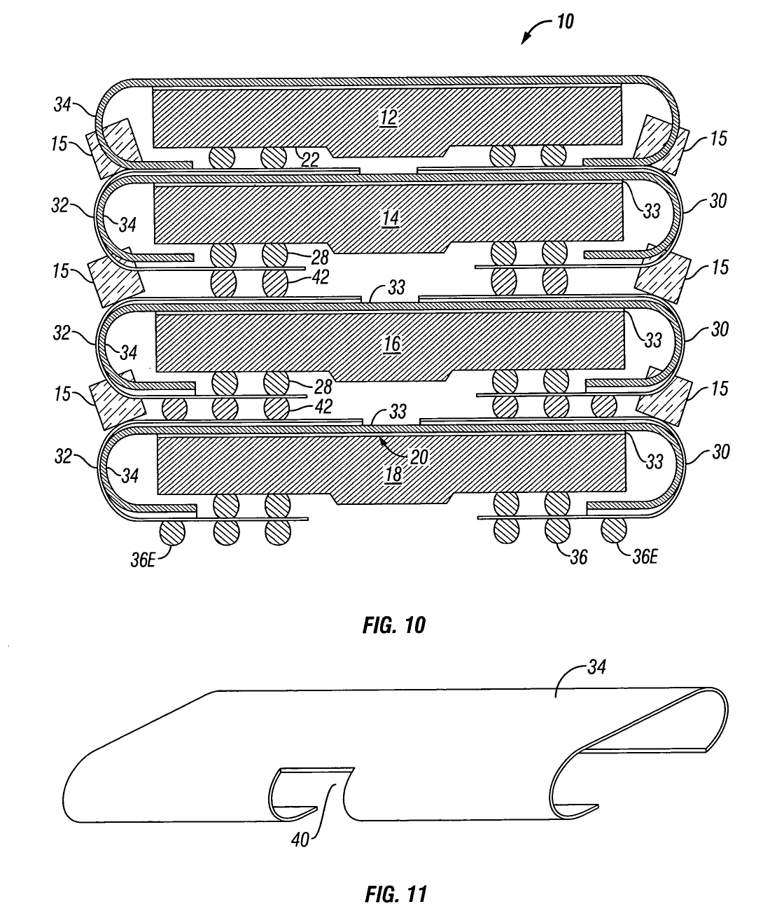

In the depicted preferred embodiment, flex contact 54 at the level of conductive layer 52 and flex contact 56 at the level of conductive layer 50 provide contact sites to allow connection of module contact 36 and CSP contact 28 through via 58. Other flex contacts 54 may not be so connected by a via 58, but may instead be electrically isolated from their opposing flex contact 56, or may be electrically connected by other structures. While a module contact 36 is shown, the same construction is preferred for an inter-flex contact 42 (FIG. 10). Further, flex contacts 54 may be presented without a corresponding flex contact 56 in a manner devised to make supplemental inter-flex connections or supplemental module contact connections. Such supplemental connections may be outside of the footprint presented by CSP contact 28 at any level of module 10, and may provide electrical connection between an operating environment any CSP in module 10.

With continuing reference to FIG. 6, optional outer layer 53 is shown over conductive layer 52 and, as those of skill will recognize, other additional layers may be included in flex circuitry employed in the invention, such as a protective inner layer over conductive layer 50, for example. Flexible circuits that employ only a single conductive layer such as, for example, those that employ only a layer such as conductive layer 52 may be readily employed in embodiments of the invention. The use of plural conductive layers provides, however, advantages and the creation of a distributed capacitance across module 10 intended to reduce noise or bounce effects that can, particularly at higher frequencies, degrade signal integrity, as those of skill in the art will recognize. Form standard 34 is seen in the depiction of FIG. 6 attached to conductive layer 50 of flex circuit 30 with metallic bond or adhesive 35.

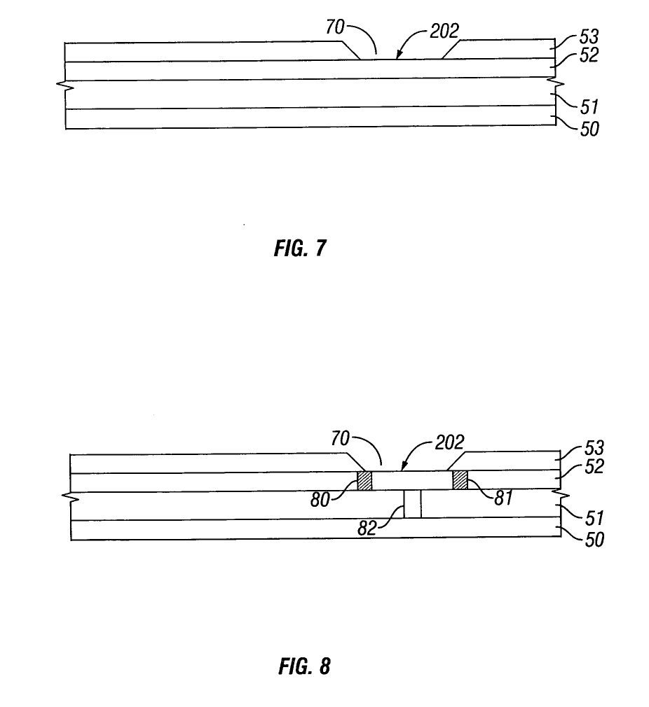

FIG. 7 depicts a portion of a flex circuit 30 according to one embodiment of the present invention. In this embodiment, conductive layer 52 expresses mounting pad 202 for connection to capacitor 15. Optional outer layer 53 has window 70 to provide access to mounting pad 202. Trace 203 is expressed at conductive layer 52. Construction of flex circuitry with such conductive layers and traces is known in the art. While a flex with two conductive layers, 50 and 52, is shown, other embodiments may have one or more than two conductive layers. The two layer arrangement shown is preferred. Further, particular embodiments with a single flex circuit may be readily constructed in accordance with the present invention.

FIG. 8 depicts an embodiment of a mounting pad 202 according to another embodiment of the present invention. In this embodiment, mounting pad 202 is electrically isolated from portions of conductive layer 52 by insulative portions 80 and 81, which may also be gaps. Mounting pad 202 is electrically connected to conductive layer 50 by via 82. In a preferred embodiment, one terminal 201 of each capacitor 15 is mounted to such a connected mounting pad 202, while the other terminal 201 is mounted to a pad 202 configured according to the embodiment in FIG. 7. Such an arrangement preferably connects one terminal 201 of capacitor 15 to a ground plane or trace at one of conductive layers 50 and 52, and the other terminal 201 to a power plane or trace at the other of conductive layers 50 and 52. Other connections and layer arrangements are possible.

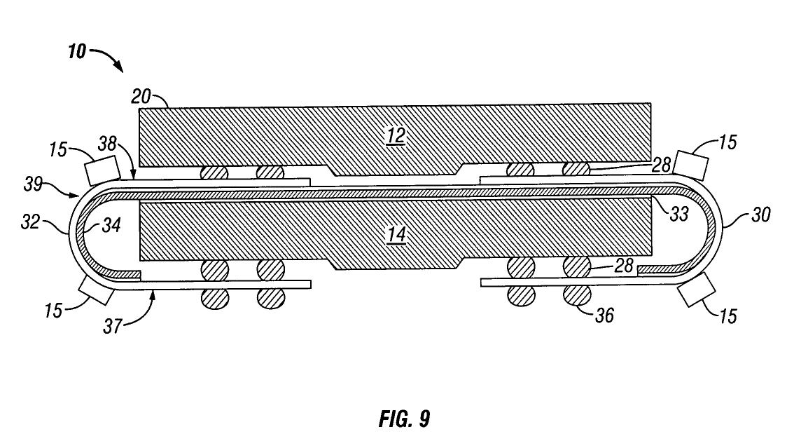

FIG. 9 depicts a module 10 according to another embodiment of the present invention. In this embodiment, capacitors 15 are mounted along the outer side of flex circuits 30 and 32, along bent portion 39 connecting lower flat portion 37 and upper flat portion 38 of each depicted flex circuit. Capacitors 15 may be mounted partially or wholly on bent portion 39.

FIG. 10 depicts a perspective view of one module 10 according to another embodiment of the present invention. In this embodiment, four CSPs 12, 14, 16, and 18 are configured in a vertical stack and interconnected with respective flex circuits 30 and 32. A form standard 34 is mounted to each of the depicted CSPs in a manner devised to provide heat transference and to provide, where appropriate, a standard-sized curved form about which flex circuits 30 and 32 are wrapped. Other shapes and configurations of form standards may be used. Some embodiments may not use form standards.

In this embodiment, each flex circuit 30 and 32 has a cutout portion 40 (FIG. 5) devised to provide clearance for a capacitor 15. Form standards 34 also have similar cutout portions 40 (FIG. 11) to provide clearance for capacitors 15. The depicted capacitors 15 are mounted along flex circuits 30 and 32 partially along the curved sides of the flex circuits. Other mounting locations may be used.

Module 10 of FIG. 10 has plural module contacts 36 and supplemental module contacts 36E. In this embodiment, form standard 34 extends underneath the depicted CSPs in a manner devised to provide support and/or thermal connectivity to supplemental module contacts 36E. Connections between flex circuits are shown as being implemented with inter-flex contacts 42 which are shown as balls but may be low profile contacts constructed with pads and/or rings that are connected with solder paste applications to appropriate connections.

FIG. 11 depicts a form standard 34 according to one embodiment of the present invention. Cutout portions 40 are present on either side of form standard 34 to allow clearance of capacitors 15 (FIG. 10). More cutouts may be used. In a preferred manner of assembling module 10, form standard 34 is made as a flat piece with cutouts, and then folded around CSPs during assembly.

Although the present invention has been described in detail, it will be apparent to those skilled in the art that many embodiments taking a variety of specific forms and reflecting changes, substitutions and alterations can be made without departing from the spirit and scope of the invention. The described embodiments illustrate the scope of the claims but do not restrict the scope of the claims.

1. A high density circuit module comprising:
two or more CSPs arranged in a stacked disposition having one or more adjacent pairs of the two or more CSPs, each of the one or more adjacent pairs having a selected upper CSP and a selected lower CSP, each of the CSPs having first and second opposing lateral sides defining a lateral extent of the CSP, each of the CSPs having a top major surface and a bottom major surface, each of the CSPs having CSP contacts along the bottom major surface;
one or more form standards attached to respective lower CSPs of selected adjacent pairs of CSPs in the module;
one or more flex circuits connecting the upper CSP and lower CSP of each of selected ones of the adjacent pairs to each other, each of the one or more flex circuits being wrapped about a respective one of the form standards such that a first portion of the flex circuit is disposed above the respective lower CSP and a second portion of the flex circuit is disposed below the respective lower CSP, the flex circuit having an outer side and an inner side;
one or more surface-mount capacitors mounted along the outer side of at least one of the one or more flex circuits.

2. The high density circuit module of claim 1 in which at least one of the one or more surface-mount capacitors is mounted along the first portion of the flex circuit.

3. The high density circuit module of claim 1 in which at least one of the one or more surface-mount capacitors is mounted along the second portion of the flex circuit.

4. The high density circuit module of claim 1 in which the flex circuit has a bend and at least one of the one or more surface-mount capacitors is mounted along the bend.

5. The high density circuit module of claim 1 in which the surface-mount capacitors are configured as bypass capacitors.

6. The high density circuit module of claim 1 in which the two or more CSPs include a selected top CSP, and a selected respective one of the one or more form standards is attached to each respective CSP below the selected top CSP.

7. The high density circuit module of claim 6 in which each selected respective one of the form standards has a first side having a first form curve and a second side having a second form curve, a selected first flex circuit of the one or more flex circuits wrapped about the first form curve and a selected second flex circuit of the one or more flex circuits wrapped about the second form curve.

8. The high density circuit module of claim 1 in which there are one or more selected adjacent pairs of the flex circuits including an upper flex circuit and a lower flex circuit, further comprising one or more module contacts connecting the upper flex circuit to the lower flex circuit.

9. The high density circuit module of claim 1 in which one or more of the form standards has a cutout portion devised to allow clearance of a surface-mount component.

10. A high density circuit module comprising:
a plurality of CSPs arranged in a stack, each one of the plurality of CSPs having a lateral extent defined by first and second opposing lateral sides and each one of the plurality of CSPs having a top major surface and a bottom major surface and CSP contacts along the bottom major surface, the stack including one or more CSP pairs each CSP pair consisting of a lower CSP and an upper CSP;
one or more flex circuits connecting selected ones of the plurality of CSPs, each of the one or more flex circuits having an outer side and an inner side;
one or more surface-mount capacitors mounted along the outer side of at least one of the one or more flex circuits.

11. The high density circuit module of claim 9 in which at least one of the one or more surface-mount capacitors is mounted at least partially along a bend in the at least one or the one or more flex circuits.

12. The high density circuit module of claim 10 in which at least one of the one or more surface-mount capacitors is mounted at least partially along a lower portion of the bend in the at least one or more flex circuits.

13. The high density circuit module of claim 9 in which at least one of the one or more surface-mount capacitors is mounted along a first portion of one of the one or more flex circuits such that it is mounted underneath a selected one of the plurality of CSPs.

14. The high density circuit module of claim 9 further comprising one or more adjacent pairs of flex circuits comprised from the one or more flex circuits and the module further comprising inter-flex contacts connecting at least one of the one or more adjacent pairs of flex circuits.

15. The high density circuit module of claim 9 further including a form standard attached to at least one of the plurality of CSPs, the form standard having a cutout portion.

16. A method of assembling a circuit comprising the steps:
providing one or more flex circuits each having a first side and a second side, a first set of contact pads arranged in one or more arrays along the first side, a second set of contact pads arranged in one or more arrays along the second side, a third set of contact pads arranged along the second side, and one or more cutout portions;
providing a first CSP and a second CSP;
providing one or more first surface-mount capacitors;
mounting the one or more first surface-mount capacitors to an operating environment;
mounting the first CSP to the first set of contact pads;
wrapping each of the one or more flex circuits about the first CSP to present a portion of the flex circuit above the first CSP with the second side of the portion of the flex circuit facing upwards;
connecting the second CSP to the second set of contact pads;
attaching a plurality of module contacts to the third set of contact pads;
positioning the one or more flex circuits above the one or more first surface-mount capacitors such that the cutout portions are each aligned with a respective one of the surface mount capacitors;
soldering the plurality of module contacts to the operating environment such that the each of the first surface-mount capacitors is at least partially within a respective one of the cutout portions.

17. The method of claim 16 in which the one or more first surface-mount capacitors are configured as bypass capacitors.

18. The method of claim 16 in which the one or more first surface-mount capacitors have a height greater than that of the module contacts.

19. The method of claim 16 in which each of the one or more surface-mount capacitors height greater than the height of the module contacts plus the thickness of one of the one or more flex circuits.

20. The method of claim 16 further comprising the step of connecting one or more second surface-mount capacitors to at least one of the one or more flex circuits.

21. A method of assembling a stack of CSPs comprising the steps of:
providing a first CSP and a second CSP;
providing first flex circuitry having a first set of CSP contacts, a second set of CSP contacts, and mounting pads;
providing one or more discrete surface-mount components;
mounting the first CSP to the first set of CSP contacts;
wrapping the first flex circuitry about opposing sides of the first CSP;
mounting the one or more discrete surface-mount components to the mounting pads of the first flex circuitry;
electrically connecting the second CSP to the second set of CSP contacts.

22. The method of claim 21 further comprising the step of attaching module contacts to the first flex circuitry.

23. The method of claim 21 further comprising the steps of:
providing second flex circuitry;
wrapping the second flex circuitry about opposing sides of the second CSP;
electrically connecting the second flex circuitry to the first flex circuitry.

24. The method of claim 23 further comprising the step of attaching inter-flex contacts to the second flex circuitry.

25. The method of claim 23 further comprising the step of attaching supplemental inter-flex contacts to the second flex circuitry.

26. The method of claim 21 further comprising the step of attaching supplemental module contacts to the first flex circuitry.

27. The method of claim 21 in which selected first ones of the mounting pads are connected to conductive traces on a first conductive layer of the first flex circuitry and selected ones second ones of the mounting pads are connected to conductive traces on a second conductive layer of the first flex circuitry.

28. The method of claim 21 in which the step electrically connecting the second CSP to the second set of CSP contacts is done after the step of mounting the one or more discrete surface mount components to the first flex circuitry.

29. The method of claim 23 further comprising the step of mounting additional discrete surface mount components to the second flex circuitry.
